(19) United States
(12) Patent Application Publication
(10) Pub. No.: US 2024/0039247 A1
(43) Pub. Date: Feb. 1, 2024

(54) OPTOELECTRONIC SEMICONDUCTOR DEVICE AND METHOD FOR OPERATING AN OPTOELECTRONIC SEMICONDUCTOR DEVICE

(71) Applicant: ams International AG, Jona (CH)

(72) Inventors: Laurent NEVOU, Wadenswil (CH); Jean Francois SEURIN, West Windsor, NJ (US); Svenja MAUTHE, Altendorf (CH); Jens GEIGER, Thalwil (CH)

(73) Assignee: ams International AG, JONA (CH)

(21) Appl. No.: 17/875,895

(22) Filed: Jul. 28, 2022

(51) Int. Cl. H01S 5/34; H01S 5/183; H01S 5/30; H01S 5/026; G01S 7/481

(52) U.S. Cl. CPC H01S 5/3416; H01S 5/18311; H01S 5/3054; H01S 5/18361; H01S 5/0262; G01S 7/4812; G01S 7/4814

(57) ABSTRACT

An optoelectronic semiconductor device (1) comprising a semiconductor body (10) having a first region (101), a second region (102) and an active region (103) configured to emit or detect electromagnetic radiation in an emission direction (S) is described herein. The optoelectronic semiconductor device (1) further comprises a first reflector (21) arranged on a first side of the semiconductor body (10) and a second reflector (22) arranged on a second side of the semiconductor body (10), opposite the first side, a first electrode (31) and a second electrode (32), an aperture region (104) and an optical element (40) arranged downstream of the active region (103) in the emission direction (S). The emission direction (S) is oriented parallel to a stacking direction of the semiconductor body (10). The first electrode (31) is arranged on the first region (101) and the second electrode (32) is arranged between the second reflector (22) and the active region (103). Further, a method for operating an optoelectronic semiconductor device (1) is provided.

### FIELD OF INVENTION

The present application relates to an optoelectronic semiconductor device and a method for operating an optoelectronic semiconductor device.

### BACKGROUND OF INVENTION

It is an object to provide an optoelectronic semiconductor device comprising improved optical characteristics.

This object is achieved, inter alia, by an optoelectronic semiconductor device as specified in the independent patent claim. Further preferred developments constitute the subject-matter of the dependent patent claims.

### SUMMARY OF INVENTION

According to at least one embodiment of the optoelectronic semiconductor device the optoelectronic semiconductor device comprises a semiconductor body having a first region, a second region and an active region configured to emit or detect electromagnetic radiation in an emission direction. The emission direction is preferably oriented vertical to a main plane of extension of the semiconductor body. In particular, the semiconductor device is configured to emit a coherent electromagnetic radiation. Preferably, the optoelectronic semiconductor device is configured as a Vertical Cavity Semiconductor Laser device (for short VCSEL).

According to at least one embodiment the optoelectronic semiconductor device comprises a first reflector arranged on a first side of the semiconductor body and a second reflector arranged on a second side of the semiconductor body, opposite the first side. The first and second reflector preferably comprise a high reflectivity for electromagnetic radiation which is emitted in the active region during operation. Advantageously, a laser cavity is formed between the first reflector and the second reflector.

According to at least one embodiment the optoelectronic semiconductor device comprises a first electrode and a second electrode. A current for operating the optoelectronic semiconductor device is flowing between the first electrode and the second electrode. The first and second electrode are formed with a metal or a metal alloy for example.

According to at least one embodiment the optoelectronic semiconductor device comprises an aperture region. The aperture region can confine an electric current in the semiconductor body in a lateral direction. The lateral direction is oriented parallel to the main plane of extension of the semiconductor body. By confining the electric current, a lateral extension of light emission can also be achieved. Advantageously, the semiconductor device emits a single mode electromagnetic radiation.

According to at least one embodiment the optoelectronic semiconductor device comprises an optical element arranged downstream of the active region in the emission direction. The optical element is for example a refractive or a diffractive element. Preferably, the optical element is permeable for the electromagnetic radiation generated in the active region during operation.

According to at least one embodiment of the optoelectronic semiconductor device the emission direction is oriented parallel to a stacking direction of the semiconductor body. For example, the stacking direction is the direction in which the semiconductor regions of the semiconductor body are grown onto each other. The stacking direction is in particular vertically oriented with respect to a main plane of extension of the active region.

According to at least one embodiment of the optoelectronic semiconductor device the first electrode is arranged on the first region and the second electrode is arranged between the second reflector and the active region. Preferably, the first electrode is arranged directly on the first region. The second electrode can have a direct contact to the second region. Electric current can be injected in the semiconductor body without passing through one of the first or second reflector. Thus, the first and second electrodes are advantageously arranged in a way which enables a very low electrical resistance of the optoelectronic semiconductor device.

According to at least one embodiment of the optoelectronic semiconductor device the optoelectronic semiconductor device comprises:
a semiconductor body having a first region, a second region and an active region configured to emit or detect electromagnetic radiation in an emission direction,
a first reflector arranged on a first side of the semiconductor body and a second reflector arranged on a second side of the semiconductor body, opposite the first side,
a first electrode and a second electrode,
an aperture region, and
an optical element arranged downstream of the active region in the emission direction, wherein
the emission direction is oriented parallel to a stacking direction of the semiconductor body,
the first electrode is arranged on the first region and the second electrode is arranged between the second reflector and the active region.

An optoelectronic semiconductor device described herein is, inter alia, based on the following considerations: New measurement applications are focused on self-mixing interferometry (short SMI) sensors based on semiconductor lasers. These can be regarded as a low cost, compact and robust solution for velocity and displacement measurement. Especially VCSEL devices have been found suitable for the use in SMI sensing applications. In common applications, often a fluctuation in the optical power output is monitored by an additional photodiode in order to measure an SMI signal, because a fluctuation in a forward voltage often is disturbed by a high noise level and thus a relatively bad Signal-to-Noise-Ratio (short SNR) occurs.

The optoelectronic semiconductor device described herein is, among other things, based on the idea of using an optoelectronic semiconductor device having a plurality of improvements to lower an electrical resistance to decrease a noise level in the forward voltage in the semiconductor device. By decreasing the noise level, the use of the forward voltage as SMI signal is greatly facilitated and a monitor diode for monitoring an optical power output can be disposed of. The electrical resistivity is inter alia decreased by an increase in a diameter of the aperture region and/or a use of a tunnel junction.

According to at least one embodiment of the optoelectronic semiconductor device the aperture region comprises a diameter between 4 μm and 10 μm. Here and in the following, the diameter of the aperture region is measured in a direction parallel to the main plane of extension of the semiconductor body and transverse to the stacking direction of the semiconductor body. The diameter of the aperture region influences a variety of parameters. Inter alia, a smaller diameter of the aperture region results in higher electrical resistance of the semiconductor body. A high electrical resistance can result in a significantly higher operational temperature and other unwanted effects.

A larger diameter of the aperture region can result in an emission of an electromagnetic radiation comprising a multiplicity of optical modes, thus disturbing a single mode operation.

According to at least one embodiment of the optoelectronic semiconductor device the aperture region comprises a diameter between 6 μm and 8 μm. An aperture region having a diameter between 6 μm and 8 μm can maintain a single modal optical emission while having an advantageously low electrical resistivity.

According to at least one embodiment of the optoelectronic semiconductor device the aperture region comprises an oxide aperture. An oxide aperture is a region comprising an oxide material having a relatively high electrical resistance compared to the other material of the semiconductor body. Thus, the oxide aperture is configured to confine an electric current in a lateral dimension. The oxide aperture is arranged preferably at the lateral edges of the semiconductor body, where only a low or no current flow is desired. Consequently, a current flow can be confined to a lateral center of the semiconductor body by the oxide aperture.

According to at least one embodiment of the optoelectronic semiconductor device the aperture region comprises a tunnel junction. A tunnel junction is a point where two different electrically conductive materials meet, usually separated by a thin barrier, for the purpose of passing electrons from one material to the other. The defining aspect of a tunnel junction is that, mechanically speaking, the electrons are too weak to penetrate the junction barrier but do so anyway though a principle called quantum tunneling. The tunnel junction is a region comprising a relatively low electrical resistance compared to the other material of the semiconductor body. Thus, the tunnel junction allows a high current flow. The tunnel junction is arranged preferably in the lateral center of the semiconductor body, where a high current flow is desired. The tunnel junction preferably has a lower thermal resistance than the material of an oxide aperture. Advantageously, the tunnel junction reduces an electrical resistance of the semiconductor device while maintaining a high thermal conductivity.

According to at least one embodiment of the optoelectronic semiconductor device the tunnel junction is a buried tunnel junction. Preferably, the buried tunnel junction is buried in the n-doped region of the semiconductor body, more preferably the first region of the semiconductor body.

According to at least one embodiment of the optoelectronic semiconductor device a doped spacer layer is arranged between the tunnel junction and the active layer. The doped spacer layer is for example exact adversely doped than the second region. For example, the doped spacer layer is p-doped if the second region is n-doped and vice versa.

According to at least one embodiment of the optoelectronic semiconductor device the first region and the second region are n-doped, and the spacer layer is p-doped. This doping enables a preferably low electrical resistivity of the semiconductor device.

According to at least one embodiment of the optoelectronic semiconductor device the optical element is suitable for collimating an electromagnetic radiation generated in the active region. The collimation of the emitted electromagnetic radiation for example enables simpler further use of the radiation, as only a limited further divergence occurs.

According to at least one embodiment of the optoelectronic semiconductor device the optoelectronic semiconductor device comprises a substrate which is structured to function as an optical element. The substrate is preferably arranged on a side of the second reflector remote from the active region. In particular, the substrate is a growth substrate of the semiconductor body and/or the second reflector. In other words, the regions of the semiconductor body and/or the second reflector are grown on the substrate. Advantageously, the substrate is permeable for electromagnetic radiation generated in the active region during operation. The substrate can be structured to have the form of a collimation lens for the radiation emitted from the active region during operation. Preferably, the surface of the substrate facing away from the active region comprises a structure which is suitable for collimating electromagnetic radiation emitted in the active region during operation.

According to at least one embodiment of the optoelectronic semiconductor device the optical element is designed such that at least some of the electromagnetic radiation generated in the active region can re-enter the semiconductor body after exiting the semiconductor device. In other words, the optical element is permeable for the electromagnetic radiation emitted from the active region during operation and exiting the semiconductor body, as well as for electromagnetic radiation in the opposite direction. Preferably, the optical element allows re-entering radiation in the semiconductor body for the use in self-mixing interferometry applications.

According to at least one embodiment of the optoelectronic semiconductor device the active region emits electromagnetic radiation with a wavelength between 400 nm and 1600 nm. In other words, the optoelectronic semiconductor device can be applied to any VCSEL kinds that emit an electromagnetic radiation having a wavelength between 400 nm to 1600 nm. Preferably the active region emits electromagnetic radiation with a wavelength between 800 nm and 1200 nm, particularly preferably the active region emits electromagnetic radiation with a wavelength between 900 nm and 1100 nm.

According to at least one embodiment of the optoelectronic semiconductor device the first reflector and the second reflector are formed as Distributed Bragg Reflectors, each comprising a plurality of alternating layers. In particular, the alternating layers have different refractive indices. Such a reflector can have a high optical reflectivity for wavelengths which satisfy the Bragg requirement.

According to at least one embodiment of the optoelectronic semiconductor device the first reflector is made from a different material than the second reflector.

The first reflector is preferably made from an oxide. For example, the first reflector can be made in a different method and can be placed onto the semiconductor body in a separate method step.

According to at least one embodiment of the optoelectronic semiconductor device the second reflector comprises a plurality of n-doped layers. Advantageously, n-doped layers can reveal a relatively low electrical resistance compared to p-doped layers. This facilitates the injection of current into the second region.

A method for operating an optoelectronic semiconductor device is also disclosed. The method for operating an optoelectronic semiconductor device is particularly suitable for operating an optoelectronic semiconductor device described here. This means that all features disclosed in connection with the optoelectronic semiconductor device are also disclosed for the method for operating the optoelectronic semiconductor device and vice versa.

According to at least one embodiment of the method for operating an optoelectronic semiconductor device the device is used for measuring a distance of a target to the optoelectronic semiconductor device. For example, the target is illuminated by electromagnetic radiation emitted by the semiconductor device during operation.

According to at least one embodiment of the method for operating an optoelectronic semiconductor device the device is used in a self-mixing interferometry application. Self-mixing interferometry is a sensing technique used to detect small relative displacements, velocity, change in the refractive index of materials, and flow. The self-mixing phenomenon occurs when a laser beam is partially reflected from an external target and injected back into a laser cavity. The reflected light interferes or ‘mixes’ with the light inside the laser cavity and inter alia produces variations to the threshold gain, emitted power, lasing spectrum and the laser junction voltage. The reflected light can be frequency shifted, by means of Doppler effect, before being mixed with the original laser emission. The resulting output power variations are usually monitored by a photodiode integrated within the laser package. This phenomenon allows the laser to be used as an interferometric sensor incorporating the light source and the interferometer in one device thus significantly reducing the cost and the complexity of the sensing system. The coherent detection nature of this sensing scheme inherently provides very high sensitivity, frequently at the quantum noise limit.

In operation, the optoelectronic semiconductor device emits electromagnetic radiation in the emission direction towards a target. The emitted radiation is at least partially reflected by the target. The reflected radiation propagates from the target back towards the optoelectronic semiconductor device. Consequently, the reflected emission re-enters the optoelectronic semiconductor device through the optical element and interferes with electromagnetic radiation generated in the active region. Thus, a self-mixing interferometry measurement can be achieved. By monitoring variations to for example the threshold gain, emitted power, lasing spectrum and the forward voltage of the optoelectronic semiconductor device one can determine for example a distance of the target from the device.

According to at least one embodiment of the method for operating an optoelectronic semiconductor device a forward voltage of the semiconductor device is measured in order to gain a self-mixing interferometry signal. The use of a semiconductor device as described herein for a self-mixing interferometry application enables the particularly simple measurement of the self-mixing interferometry signal by measuring the forward voltage of the device. This is achieved by decreasing the resistance of the semiconductor device to a level where for example shot noise and thermal noise is low enough to effectively use the forward voltage as signal for the self-mixing interferometry signal. Thus, advantageously no monitor diode for measuring a power output is needed.

An optoelectronic semiconductor device described herein is particularly suitable for use in any application that uses SMI-measurements, for example finger sliders, optical microphones, eye tracker, rotary encoders, vital sensors or loud speaker feedback.

Further advantages and advantageous designs and further developments of the optoelectronic semiconductor device result from the following exemplary embodiments, which are described below in association with the figures.

### BRIEF DESCRIPTION OF THE DRAWINGS

In the figures:

FIG. 1 shows a schematic side view of an optoelectronic semiconductor device described herein according to a first exemplary embodiment,

FIG. 2 shows a schematic plan view of an optoelectronic semiconductor device described herein according to a second exemplary embodiment,

FIG. 3 shows a schematic plan view of an optoelectronic semiconductor device described herein according to a third exemplary embodiment,

FIG. 4 shows a schematic plan view of an optoelectronic semiconductor device described herein according to a fourth exemplary embodiment,

FIG. 5 shows a schematic plan view of an optoelectronic semiconductor device described herein according to a fifth exemplary embodiment, and

FIGS. 6A and 6B show a voltage signal of an SMI signal and a corresponding noise signal of two optoelectronic semiconductor devices described herein.

### DETAILED DESCRIPTION

Identical, similar or equivalent elements are marked with the same reference signs in the figures. The figures and the proportions of the elements represented in the figures among each other are not to be considered as true to scale. Rather, individual elements may be oversized for better representability and/or comprehensibility.

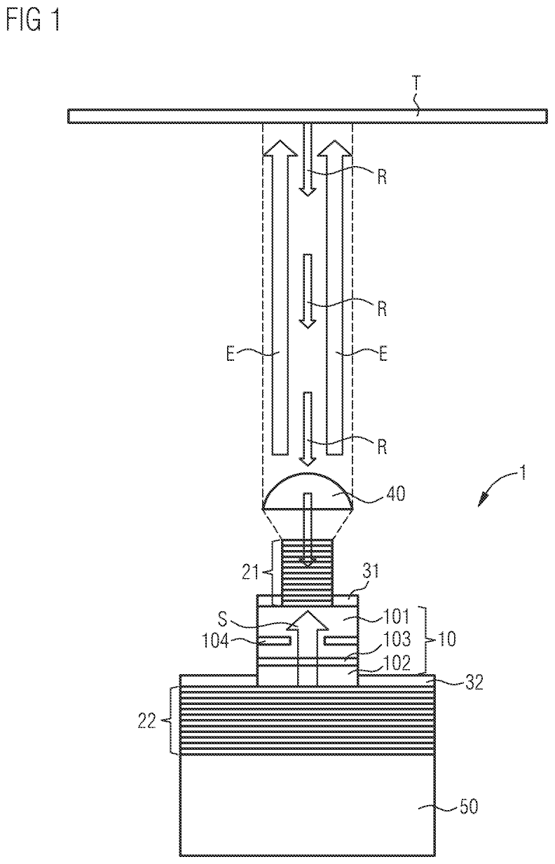

FIG. 1 shows a schematic side view of an optoelectronic semiconductor device 1 described herein according to a first exemplary embodiment. The optoelectronic semiconductor device 1 comprises a semiconductor body 10 having a first region 101, a second region 102 and an active region 103 configured to emit or detect electromagnetic radiation in an emission direction S. The active region 103 is arranged between the first region 101 and the second region 102. The emission direction S is preferably oriented vertical to a main plane of extension of the semiconductor body 10. The emission direction S is oriented parallel to a stacking direction of the semiconductor body 10. For example, the stacking direction is the direction in which the semiconductor regions of the semiconductor body 10 are grown onto each other. The stacking direction is in particular vertically oriented with respect to a main plane of extension of the active region 103.

In particular, the semiconductor device 1 is configured to emit a coherent electromagnetic radiation. The optoelectronic semiconductor device 1 according to FIG. 1 is configured as a Vertical Cavity Semiconductor Laser device (for short VCSEL).

Furthermore, the optoelectronic semiconductor device 1 comprises a first reflector 21 arranged on a first side of the semiconductor body 10 and a second reflector 22 arranged on a second side of the semiconductor body 10, opposite the first side. The first reflector 21 is in direct contact with the first region 101. The second reflector 22 is in direct contact with the second region 102.

The first and second reflectors 21, 22 preferably comprise a high reflectivity for an electromagnetic radiation which is emitted in the active region 103 during operation. Advantageously, a laser cavity is formed between the first reflector 21 and the second reflector 22. The first reflector 21 and the second reflector 22 are formed as Distributed Bragg Reflectors, each comprising a plurality of alternating layers. In particular, the alternating layers have different refractive indices. Such a reflector can have a high optical reflectivity for wavelengths which satisfy the Bragg requirement.

The optoelectronic semiconductor device 1 further comprises a first electrode 31 and a second electrode 32. The first electrode 31 is intended to inject a current into the first region 101 and the second electrode is intended to inject a current into to the second region 102. The first and second electrodes 31, 32 are formed with a metal or a metal alloy for example. The first electrode 31 is arranged on the first region 101 and the second electrode 32 is arranged between the second reflector 22 and the active region 103. Preferably, the first electrode 31 is arranged directly on the first region 101. The second electrode 32 can have a direct contact to the second region 102. The first electrode 31 preferably comprises a hole in the lateral center of the semiconductor body 10. The first reflector 31 is preferably arranged in the hole of the first electrode 31.

Electric current can be injected in the semiconductor body 10 without passing through one of the first or second reflectors 21, 22. Thus, the first and second electrodes 31, 32 are advantageously arranged in a way which enables a very low electrical resistance of the optoelectronic semiconductor device 1.

Moreover, the optoelectronic semiconductor device 1 comprises an aperture region 104. The aperture region 104 is arranged in the first region 101. In particular, the aperture region 104 is at least partially embedded in the first region 101.

The aperture region 104 can confine an electric current in the semiconductor body 10 in a lateral direction. The lateral direction is oriented parallel to the main plane of extension of the semiconductor body 10. By confining the electric current, a lateral extension of light emission can also be achieved. Advantageously, the optoelectronic semiconductor device 1 emits a single mode electromagnetic radiation. The aperture region 104 according to FIG. 1 comprises an oxide aperture. An oxide aperture is a region comprising an oxide material having a relatively high electrical resistance compared to the other material of the semiconductor body 10. Thus, the oxide aperture is configured to confine an electric current in a lateral dimension. The oxide aperture is arranged preferably at the lateral edges of the semiconductor body 10, where only a low or no current flow is desired. Consequently, a current flow can be confined to a lateral center of the semiconductor body 10 by the oxide aperture.

The optoelectronic semiconductor device 1 comprises a substrate 50 which is arranged on a side of the second reflector 22 remote from the active region 103. In particular, the substrate 50 is a growth substrate of the semiconductor body 10 and/or the second reflector 22. In other words, the first region 101, the active region 103 and the second region 103 of the semiconductor body 10 and/or the second reflector 22 are grown on the substrate 50.

The optoelectronic semiconductor device 1 comprises an optical element 40 arranged downstream of the active region 103 in the emission direction S. The optical element 40 is for example a refractive or a diffractive element. Preferably, the optical element 40 is permeable for the electromagnetic radiation generated in the active region 103 during operation. The optical element 40 is suitable for collimating an electromagnetic radiation generated in the active region 103 during operation. The collimation of the emitted electromagnetic radiation for example enables simpler further use of the radiation, as only a limited further divergence occurs. The optical element 40 is designed such that at least some of the electromagnetic radiation generated in the active region 103 during operation can re-enter the semiconductor body 10 after exiting the semiconductor device 1. In other words, the optical element 40 is permeable for the electromagnetic radiation emitted from the active region 103 during operation and exiting the semiconductor body 10, as well as for electromagnetic radiation propagating in the opposite direction. In particular, the optical element 40 allows re-entering radiation in the semiconductor body 10 for the use in self-mixing interferometry applications.

The optoelectronic semiconductor device 1 is in particular suitable for the use in a self-mixing interferometry application. In such an application a beam of coherent electromagnetic radiation is emitted in the emission direction S and at least partially reflected from an external target. The reflected portion of the electromagnetic radiation can re-enter the optical element 40 and is consequently injected back into the cavity of the semiconductor body 10. The reflected electromagnetic radiation interferes or ‘mixes’ with the electromagnetic radiation inside the semiconductor body 10 and inter alia produces variations to the threshold gain, emitted power, lasing spectrum and the forward voltage.

In operation, the optoelectronic semiconductor device 1 emits radiation E in the emission direction S towards a target T. The emitted radiation E is at least partially reflected by the target T. The reflected radiation R propagates from the target T back towards the optoelectronic semiconductor device 1. Consequently, the reflected emission R re-enters the optoelectronic semiconductor device 1 through the optical element 40 and interferes with electromagnetic radiation generated in the active region 103. Thus, a self-mixing interferometry measurement can be achieved.

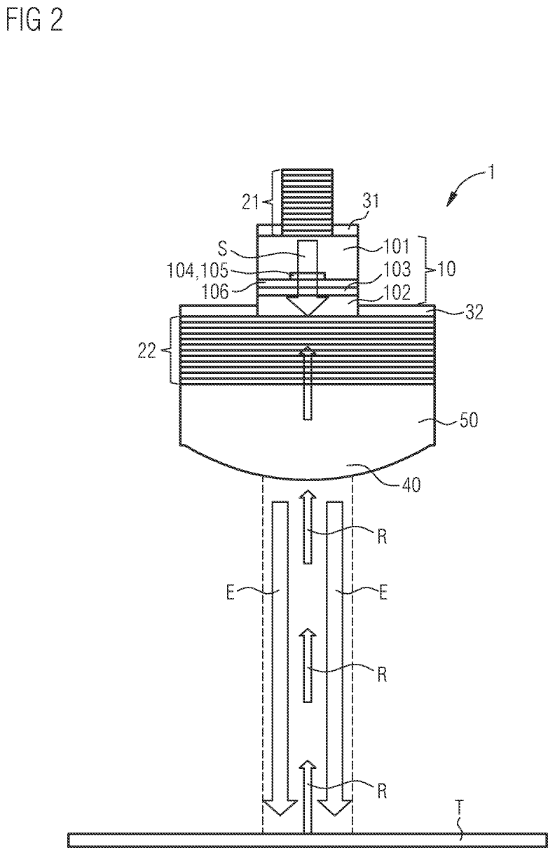

FIG. 2 shows a schematic plan view of an optoelectronic semiconductor device 1 described herein according to a second exemplary embodiment. The second exemplary embodiment essentially corresponds to the first exemplary embodiment shown in FIG. 1. However, the emission direction S according to the second exemplary embodiment is oriented in the exact opposite direction. The emission direction S is facing towards the substrate 50 starting from the active region 103.

Furthermore, the optoelectronic semiconductor device 1 comprises a substrate 50 which is structured to function as an optical element 40. The substrate 50 is permeable for electromagnetic radiation generated in the active region 103 during operation. The substrate 50 can be structured to have the form of a collimation lens for the radiation emitted from the active region 103 during operation. Preferably, the surface of the substrate 50 facing away from the active region 103 comprises a structure which is suitable for collimating electromagnetic radiation emitted in the active region 103 during operation. Thus, a further external optical element 40 is not necessary.

Moreover, the aperture region 104 comprises a tunnel junction 105. A tunnel junction 105 is a point where two different electrically conductive materials meet, usually separated by a thin barrier, for the purpose of passing electrons from one material to the other. The tunnel junction 105 is a region comprising a relatively low electrical resistance compared to the other material of the semiconductor body 10. Thus, the tunnel junction 105 allows a high current flow. The tunnel junction 105 is arranged in the lateral center of the semiconductor body 10, where a high current flow is desired. The tunnel junction 105 preferably has a lower thermal resistance than the material of an oxide aperture.

Advantageously, the tunnel junction 105 reduces an electrical resistance of the semiconductor device 1 while maintaining a high thermal conductivity.

The tunnel junction 105 is a buried tunnel junction. Preferably, the buried tunnel junction 105 is buried in the n-doped region of the semiconductor body 10, more preferably the first region 101 of the semiconductor body 10.

A doped spacer layer 106 is arranged between the tunnel junction 105 and the active layer 103. The doped spacer layer 106 is for example exact adversely doped than the second region 102. For example, the doped spacer layer 106 is p-doped if the second region 102 is n-doped and vice versa.

The first region 101 and the second region 102 are n-doped, and the spacer layer 106 is p-doped. This doping enables a preferably low electrical resistivity of the semiconductor device 1.

In operation, the optoelectronic semiconductor device 1 emits radiation E in the emission direction S towards a target T. The emitted radiation E is at least partially reflected by the target T. The reflected radiation R propagates from the target T back towards the optoelectronic semiconductor device 1. Consequently, the reflected emission R re-enters the optoelectronic semiconductor device 1 through the substrate 50 which is structured as an optical element 40 and interferes with electromagnetic radiation generated in the active region 103. Thus, a self-mixing interferometry measurement can be achieved.

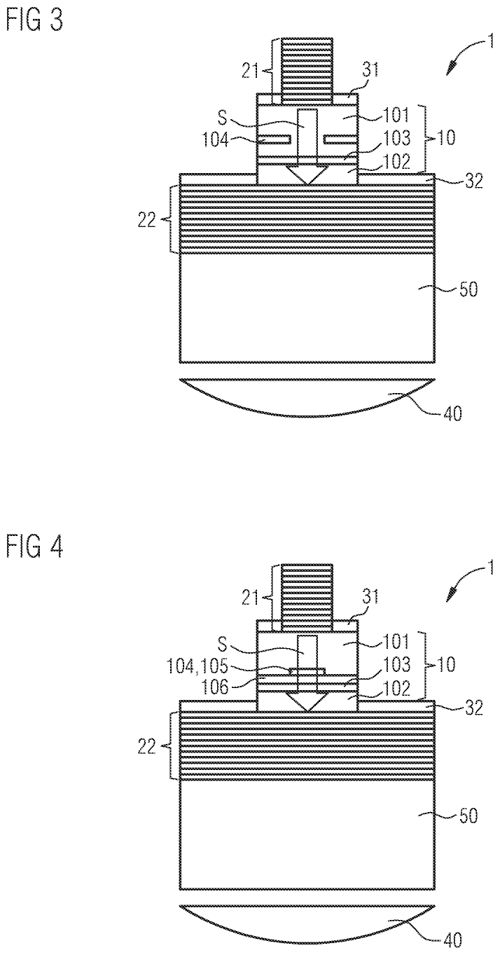

For the sake of simplicity, the further FIGS. 3 to 5 do not show a target T and the propagation of emitted radiation E and reflected radiation R.

FIG. 3 shows a schematic plan view of an optoelectronic semiconductor device 1 described herein according to a third exemplary embodiment. The third exemplary embodiment essentially corresponds to the first exemplary embodiment shown in FIG. 1. However, the emission direction S according to the third exemplary embodiment is oriented in the exact opposite direction. The emission direction S is facing towards the substrate 50 starting from the active region 103. Consequently, the optical element 40 is arranged on the side of the substrate 50 downstream of the emission direction S.

FIG. 4 shows a schematic plan view of an optoelectronic semiconductor device 1 described herein according to a fourth exemplary embodiment. The fourth exemplary embodiment essentially corresponds to the second exemplary embodiment shown in FIG. 2. However, the substrate 50 is not structured to function as an optical element 40. Thus, an external optical element 40 is arranged on the side of the substrate 50.

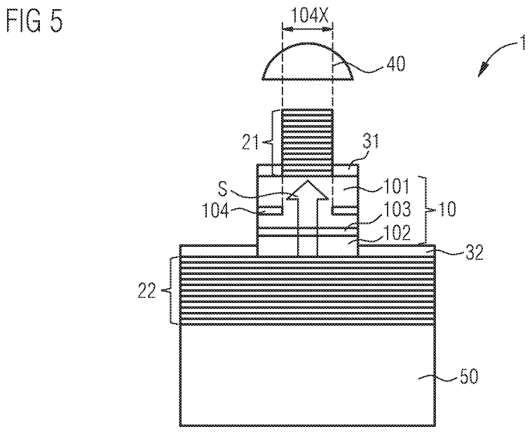

FIG. 5 shows a schematic plan view of an optoelectronic semiconductor device 1 described herein according to a fifth exemplary embodiment. The fifth exemplary embodiment essentially corresponds to the first exemplary embodiment shown in FIG. 1. However, a diameter 104X of the aperture region 104 is increased. The aperture region 104 comprises a diameter 104X between 4 μm and 10 μm. The diameter 104X of the aperture region 104 is measured in a direction parallel to the main plane of extension of the semiconductor body 10 and transverse to the stacking direction of the semiconductor body 10. The diameter 104X of the aperture region 104 influences a variety of parameters. Inter alia, a smaller diameter 104X of the aperture region 104 results in a higher electrical resistance of the semiconductor body 10. A high electrical resistance can result in a significantly higher operational temperature and other unwanted effects, for example a higher noise level in a forward voltage signal of the semiconductor device 1. A larger diameter 104X of the aperture region 104 can result in an emission of an electromagnetic radiation comprising a multiplicity of optical modes, thus disturbing a single mode operation.

Preferably, the aperture region 104 comprises a diameter 104X between 6 μm and 8 μm. An aperture region 104X having a diameter between 6 μm and 8 μm can maintain a single modal optical emission while having an advantageously low electrical resistivity.

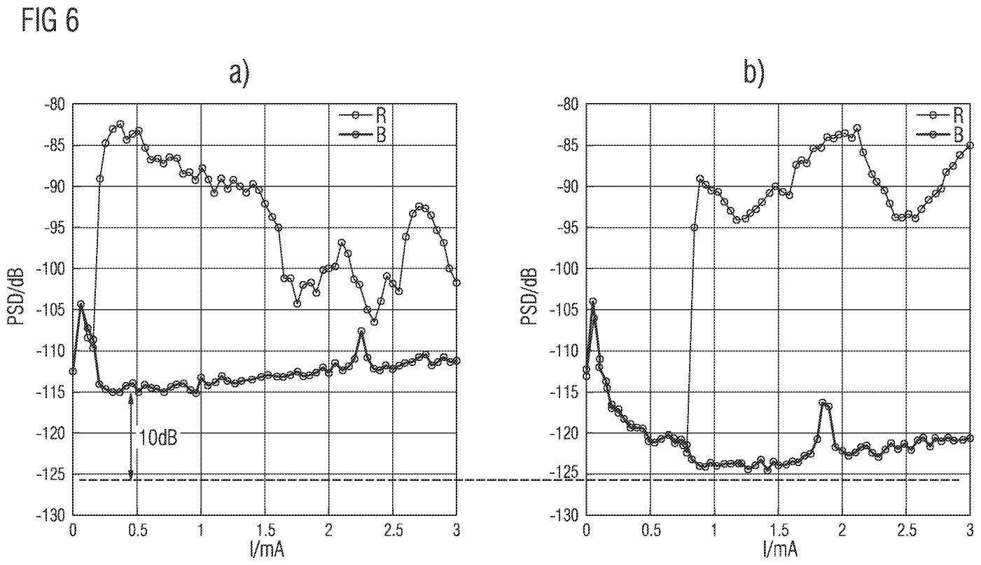

FIG. 6 shows a voltage signal of an SMI signal and a corresponding noise signal of two different optoelectronic semiconductor devices 1 described herein. The plots each show two graphs comprising a voltage signal R of an SMI signal and a noise voltage B. The plot a) on the left hand side corresponds to a semiconductor device 1 having an aperture region 104 with a diameter 104X of approximately 4 μm. The plot b) on the right hand side corresponds to a semiconductor device 1 having an aperture region 104 with a diameter 104X of approximately 13 μm. It becomes clearly visible, that the level of noise is significantly dropping by approximately 10 dB with the increase in aperture diameter 104X. This is due to the reduced electrical resistance of the semiconductor device 1 having a larger diameter 104X of the aperture region 104.

The invention described herein is not limited by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

### REFERENCES

1 optoelectronic semiconductor device
10 semiconductor body
101 first region
102 second region
103 active region
104 aperture region
105 tunnel junction
106 spacer layer
21 first reflector
22 second reflector
31 first electrode
32 second electrode
40 optical element
50 substrate
S emission direction
E emitted radiation
R reflected radiation
T target
104X aperture diameter

We claim:

1. An optoelectronic semiconductor device comprising:
a semiconductor body having a first region, a second region and an active region configured to emit or detect electromagnetic radiation in an emission direction,
a first reflector arranged on a first side of the semiconductor body and a second reflector arranged on a second side of the semiconductor body, opposite the first side,
a first electrode and a second electrode,
an aperture region, and
an optical element arranged downstream of the active region in the emission direction, wherein
the emission direction is oriented parallel to a stacking direction of the semiconductor body,
the first electrode is arranged on the first region and the second electrode is arranged between the second reflector and the active region.

2. The optoelectronic semiconductor device according to claim 1, wherein
the aperture region comprises a diameter between 4 μm and 10 μm.

3. The optoelectronic semiconductor device according to claim 1, wherein
the aperture region comprises a diameter between 6 μm and 8 μm.

4. The optoelectronic semiconductor device according to claim 1, wherein
the aperture region comprises an oxide aperture.

1. An optoelectronic semiconductor device comprising:
a semiconductor body having a first region, a second region and an active region configured to emit or detect electromagnetic radiation in an emission direction,
a first reflector arranged on a first side of the semiconductor body and a second reflector arranged on a second side of the semiconductor body, opposite the first side,
a first electrode and a second electrode,
an aperture region, and
an optical element arranged downstream of the active region in the emission direction, wherein
the emission direction is oriented parallel to a stacking direction of the semiconductor body,
the first electrode is arranged on the first region and the second electrode is arranged between the second reflector and the active region.

2. The optoelectronic semiconductor device according to claim 1, wherein
the aperture region comprises a diameter between 4 μm and 10 μm.

3. The optoelectronic semiconductor device according to claim 1, wherein
the aperture region comprises a diameter between 6 μm and 8 μm.

4. The optoelectronic semiconductor device according to claim 1, wherein
the aperture region comprises an oxide aperture.

5. The optoelectronic semiconductor device according to claim 1, wherein
the aperture region comprises a tunnel junction.

6. The optoelectronic semiconductor device according to claim 5, wherein
the tunnel junction is a buried tunnel junction.

7. The optoelectronic semiconductor device according to claim 6, wherein
a doped spacer layer is arranged between the tunnel junction and the active layer.

8. The optoelectronic semiconductor device according to claim 5, wherein
the first region and the second region are n-doped, and
the spacer layer is p-doped.

9. The optoelectronic semiconductor device according to claim 1, wherein
the optical element is suitable for collimating an electromagnetic radiation generated in the active region.

10. The optoelectronic semiconductor device according to claim 1, wherein
the optoelectronic semiconductor device comprises a substrate which is structured to function as an optical element.

11. The optoelectronic semiconductor device according to claim 1, wherein
the optical element is designed such that at least some of the electromagnetic radiation generated in the active region can re-enter the semiconductor body after exiting the semiconductor device.

12. The optoelectronic semiconductor device according to claim 1, wherein
the active region emits electromagnetic radiation with a wavelength between 400 nm and 1600 nm.

13. The optoelectronic semiconductor device according to claim 1, wherein
the first reflector and the second reflector are formed as Distributed Bragg Reflectors, each comprising a plurality of alternating layers.

14. The optoelectronic semiconductor device according to claim 1, wherein
the first reflector is made from a different material than the second reflector.

15. The optoelectronic semiconductor device according to claim 1, wherein
the second reflector comprises a plurality of n-doped layers.

16. A method for operating an optoelectronic semiconductor device according to claim 1, wherein
the device is used for measuring a distance of a target to the optoelectronic semiconductor device.

17. The method for operating an optoelectronic semiconductor device according to claim 16, wherein
the device is used in a self-mixing interferometry application.

18. The method for operating an optoelectronic semiconductor device according to claim 16, wherein
a forward voltage of the semiconductor device is measured in order to gain a self-mixing interferometry signal.
